(19) United States
(12) Patent Application Publication
(10) Pub. No.: US 2013/0009125 A1
(43) Pub. Date: Jan. 10, 2013

(54) LOW RESISTANCE SEMICONDUCTOR DEVICE

(76) Inventors: Jong-hyun PARK, Hwaseong-si (KR); Jae-hee Oh, Seongnam-si (KR); Kyu-sul Park, Suwon-si (KR)

(21) Appl. No.: 13/533,023

(22) Filed: Jun. 26, 2012

(30) Foreign Application Priority Data
Jul. 7, 2011 (KR) 10-2011-0067535

(51) Int. Cl. H01L 45/00; H01L 29/82; H01L 29/06; H01L 29/92

(52) U.S. Cl. 257/4; 257/532; 257/421; 257/653; 257/E45.001; 257/E29.323; 257/E29.342; 257/E29.005

(57) ABSTRACT

A semiconductor device includes an insulation layer including a cell contact hole, and a switching device in the cell contact hole, at least a part of a top surface of the switching device being inclined with respect to an axial direction of the cell contact hole.

### CROSS-REFERENCE TO RELATED APPLICATIONS

This application claims the benefit of Korean Patent Application No. 10-2011-0067535, filed on Jul. 7, 2011, in the Korean Intellectual Property Office, the disclosure of which is incorporated herein in its entirety by reference.

### BACKGROUND

1. Field

The inventive concept relates to a low resistance semiconductor device, and more particularly, to a semiconductor device having a very low contact resistance.

2. Description of the Related Art

Technology using phase-change material in semiconductor devices has been developed, as a size of a semiconductor device was decreased. A semiconductor device using the phase-change material may use a change in resistance according to a phase-change of the phase-change material and/or a reversible change in a phase of the phase-change material according to intensity and an endurance time of an applied voltage. The semiconductor device using the phase-change material may be coupled to a switching device, e.g., a transistor or a diode, and may be utilized as a memory device, i.e., a storage device.

### SUMMARY

The inventive concept provides a semiconductor device having a low contact resistance, low power consumption, and excellent operation characteristics.

According to an aspect of the inventive concept there is provided a semiconductor device, including an insulation layer including a cell contact hole, and a switching device in the cell contact hole, at least a part of a top surface of the switching device being inclined with respect to an axial direction of the cell contact hole.

The semiconductor device may further include a storage device electrically connected to the switching device, and a plurality of bitlines electrically connected to the storage device.

The semiconductor device may further include a bottom electrode formed at a bottom portion of the storage device, and a top electrode formed at a top portion of the storage device.

The bottom electrode may be in the cell contact hole, an entire sidewall of the bottom electrode directly contacting a sidewall of the cell contact hole.

The storage device may be at least one of a capacitor, a phase-change random access memory (PRAM), a resistive random access memory (RRAM), a ferroelectric random access memory (FRAM), and a magnetic random access memory (MRAM).

The semiconductor device may further include a metal silicide layer inside the cell contact hole and on a top surface of the switching device.

An entire top surface of the metal silicide layer may contact a bottom surface of a bottom electrode of the storage device, and an entire bottom surface of the metal silicide layer contacts the top surface of the switching device.

The switching device may be a diode.

An angle between the top surface of the diode and the axial direction of the cell contact hole may be about 30 degrees to about 80 degrees.

A cross-section of the cell contact hole may be oval or rectangular.

An aspect ratio of the cross-section of the cell contact hole may be about 1.2 to about 3.

The surface of the switching device may be located between about 20% and about 80% of a height of the cell contact hole.

A storage device may overlap the entire top surface of the switching device, a surface area of the top surface of the switching device being larger than a surface of area of a bottom of the cell contact hole.

At least a portion of the top surface of the switching device and a bottom surface of the switching device may not be parallel, the bottom surface of the switching device being substantially perpendicular to the axial direction of the cell contact hole, and a bottom surface of a storage device being on and parallel to the top surface of the switching device.

A surface area of the top surface of the switching device may be larger than a surface area of the bottom surface of the switching device.

A bottom of a storage device may be on and parallel to the top surface of the switching device, a surface area of the top surface of the switching device being larger than a surface area of a bottom of the cell contact hole.

According to an aspect of the inventive concept there is provided a semiconductor device, including a substrate, and a switching device with a p-n junction on the substrate, the substrate being a seed crystal for the switching device, and at least a part of a top surface of the switching device being inclined with respect to a surface of the substrate.

An interface of the p-n junction may be non parallel to the surface of the substrate.

The switching device may be epitaxially grown from the substrate, the p-n junction being within a portion of the epitaxially grown switching device.

According to an aspect of the inventive concept there is provided a method of forming a semiconductor device, the method including epitaxially growing a layer on a substrate, and implanting ions in the epitaxially grown layer to form a switching device with a p-n junction on the with respect to a surface of the substrate.

### BRIEF DESCRIPTION OF THE DRAWINGS

Features will become apparent to those of ordinary skill in the art by describing in detail exemplary embodiments with reference to the attached drawings, in which:

FIG. 1 illustrates a conceptual diagram of a layout of a semiconductor device, according to an embodiment of the inventive concept;

FIG. 2 illustrates a side cross-sectional view of a semiconductor device, according to an embodiment of the inventive concept;

FIGS. 3A and 3B illustrate plan views of a cell contact hole, according to an embodiment of the inventive concept;

FIGS. 4A and 4B illustrate perspective views of a cell contact hole, a p-n junction diode, and an ohmic layer, according to an embodiment of the inventive concept;

FIGS. 5 through 10 illustrate cross-sectional views of semiconductor devices, according to other embodiments of the inventive concept; and

FIGS. 11A through 11G illustrate cross-sectional views of stages in a method of manufacturing a semiconductor device, according to an embodiment of the inventive concept.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the embodiments to those skilled in the art.

In the drawing figures, the dimensions of layers and regions may be exaggerated for clarity of illustration. It will also be understood that when a layer (or element) is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could not be termed a second element, component, region, layer or section without departing from the teachings of the inventive concept.

The terminology used herein is for the purpose of describing particular embodiments only and is not intended to be limiting of the inventive concept. The singular forms include the plural forms unless the context clearly indicates otherwise. It will further understood that the terms “comprise” and/or “comprising” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used in dictionaries, should be interpreted as having a meaning that is consistent with their meaning in the context of the relevant art and will not be interpreted in an idealized or overly formal senses unless expressly so defined herein.

The inventive concept provides a semiconductor device including an insulation layer, in which a cell contact hole is formed, and a switching device having a top surface inclined with respect to an axial direction of the cell contact hole.

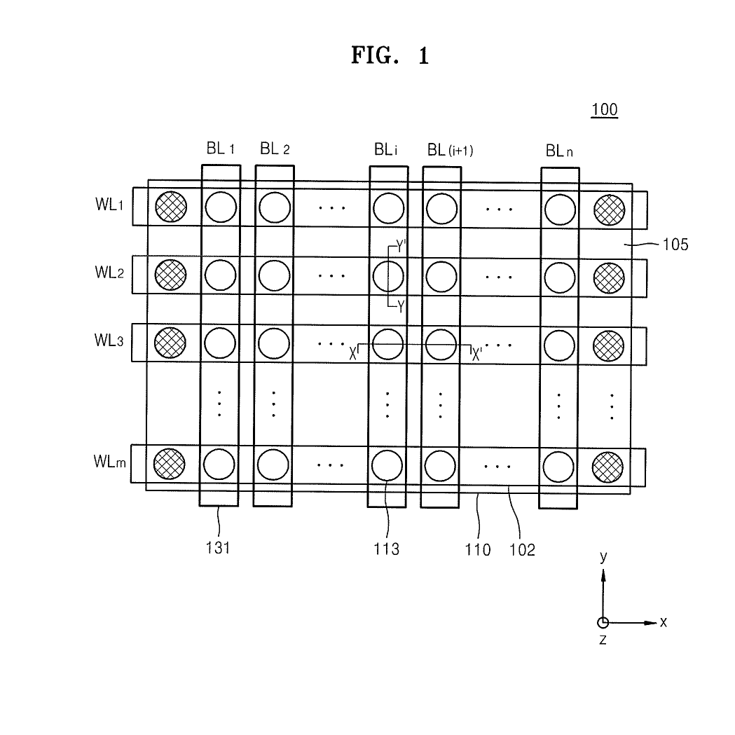

FIG. 1 illustrates a layout of a semiconductor device 100, according to an embodiment of the inventive concept. Referring to FIG. 1, a plurality of word lines 102, e.g., word lines WL₁, WL₂, WL₃, . . . , WLₘ, extend in a first direction, e.g., along an x direction, and are arranged in a second direction, e.g., spaced apart from each other in a y direction, in a cell region 110 of the semiconductor device 100. Although the first direction and the second direction are perpendicular to each other in FIG. 1, the inventive concept is not limited thereto, as long as the first direction and the second direction are different from each other. The word lines 102 may be isolated from each other, e.g., along the y direction, by a device isolation layer 105.

A plurality of bit lines 131, e.g., a plurality of bit lines BL₁, BL₂, . . . , BLᵢ, BL₍ᵢ₊₁₎, . . . , BLₙ, may extend in the second direction, and may be electrically connected to the word lines 102 via p-n junction diodes 113 interposed therebetween. Although not shown, the semiconductor device 100 may further include storage devices corresponding to the p-n junction diodes 113. Alternatively, the semiconductor device 100 may further include a strained film (not shown) to apply stress to the word lines 102 in a horizontal direction.

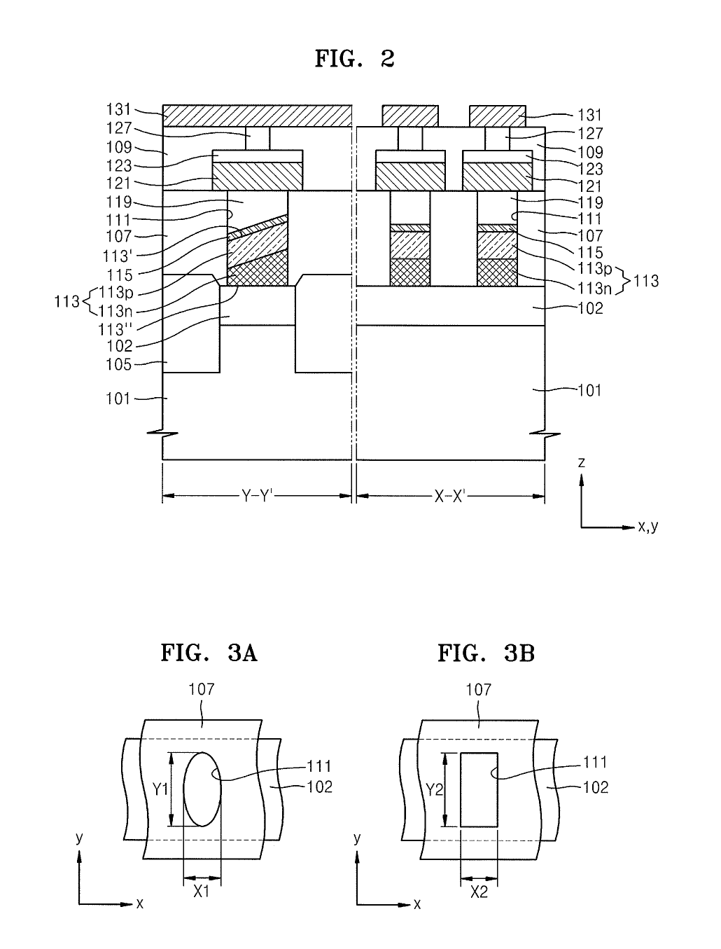

FIG. 2 is a side cross-sectional view of portions X-X′ and Y-Y′ of the semiconductor device 100 of FIG. 1. The X-X′ portion is a cross-section of the semiconductor device 100 cut in the x direction. The Y-Y′ portion is a cross-section of the semiconductor device 100 cut in the y direction.

Referring to FIGS. 1 and 2, active regions may be isolated from each other by the device isolation layer 105, and may extend on a semiconductor substrate 101 in the x direction The semiconductor substrate 101 may include a semiconductor material, e.g., a Group IV semiconductor material, a Group III-V compound semiconductor material, or a Group II-VI oxide semiconductor material. For example, the Group IV semiconductor material may include silicon, germanium, or silicon-germanium. The semiconductor substrate 101 may be provided as a bulk wafer or an epitaxial layer. Alternatively, the semiconductor substrate 101 may be a silicon-on-insulator (SOI) substrate, a gallium-arsenic substrate, and/or a silicon-germanium substrate. The semiconductor substrate 101 may include unit devices (not shown) necessary for forming a semiconductor apparatus, for example, various types of active devices or passive devices.

The device isolation layer 105 may be formed on the semiconductor substrate 101 to isolate the unit devices from each other. For example, the device isolation layers 105 may be formed by using a local oxidation of silicon (LOCOS) process or a shallow trench isolation (STI) process. The semiconductor substrate 101 may include an insulation layer (not shown) that covers the unit device, conductive regions (not shown) that are electrically connected to the unit devices, and conductive wires (not shown) that connect the unit devices or the conductive regions.

The word lines 102 may be formed in the active regions by doping impurities. For example, the word lines 102 may be formed by injecting impurities having high density. The density of impurities used to form the word lines 102 may be, for example, 1×10²⁰ ion/cm³ and 1×10²² ion/cm³. The impurities may include n type impurities, e.g., arsenic (As), phosphorus (P), antimony (Sb), and/or bismuth (Bi), or p type impurities, e.g., boron (B), indium (In), and/or gallium (Ga).

A first interlayer insulation layer 107 including a cell contact hole 111 may be formed on the word lines 102. The first interlayer insulation layer 107 may be formed, e.g., of at least one of BPSG (boro-phospho-silicate glass), TOSZ (tonen silazene), USG (undoped silicate glass), SOG (spin-on glass), FOX (flowable oxide), TEOS (tetraethylortho silicate) or HDP CVD (high density plasma chemical vapor deposition) oxide. Optionally, the first interlayer insulation layer 107 may further include silicon nitride.

The cell contact hole 111 may extend in a perpendicular direction in such a way that the cell contact hole 111 passes through the first interlayer insulation layer 107 toward the word lines 102. For example, a cross-section of the cell contact hole 111, e.g., in the xy-plane as seen from a plane view, may be circular, as illustrated in FIG. 1. In another example, the cell contact hole 111 may have an oval cross-section having major and minor axes, a square cross-section, a rectangular cross-section, and other polygonal cross-sections. The cross-sectional area of the cell contact hole 111 in a horizontal direction may vary according to a location of the cell contact hole 111 in the perpendicular direction. However, the actual location, i.e., position, of the cell contact hole 111 in the horizontal direction may not vary, so the cell contact hole 111 may be located on the word lines 102, i.e., the cell contact hole 111 may extend substantially perpendicularly to the substrate 101 to expose a portion of an upper surface of a respective word line 102.

The cell contact hole 111 may include the p-n junction diodes 113 as switching devices. The p-n junction diodes 113 may grow from the active regions located thereunder using selective epitaxial growth (SEG). Although an n type semiconductor layer 113n of the p-n junction diodes 113 is located as a lower layer, and a p type semiconductor layer 113p thereof is located as an upper layer in FIG. 2, such locations may be changed. An ion injection density of the n type semiconductor layer 113n may be, for example, about 1×10¹⁸ ion/cm³ to about 1×10²⁰ ion/cm³. An ion injection density of the p type semiconductor layer 113p may be, for example, about 1×10²⁰ ion/cm³ to about 1×10²² ion/cm³.

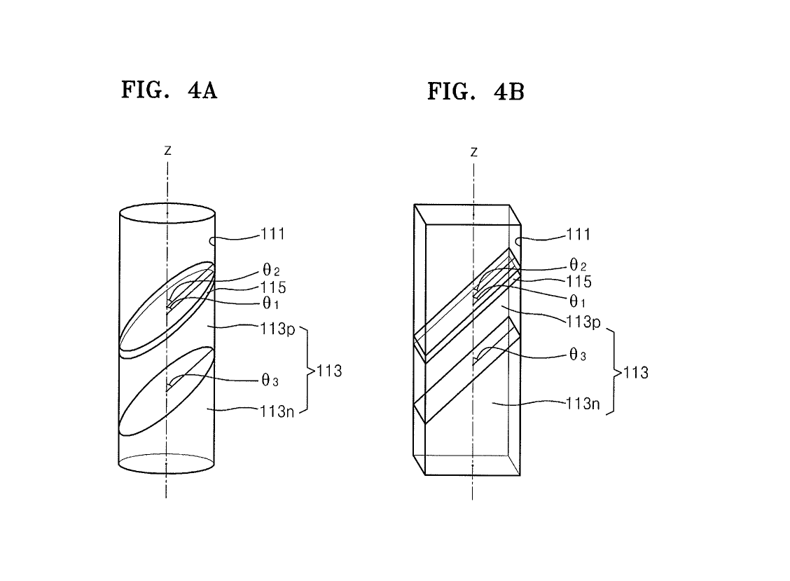

A top surface 113′ of the p-n junction diodes 113 may be inclined with respect to an axial direction of the cell contact hole 111, e.g., the top surface 113′ may be positioned at an oblique angle with respect to the z-axis. This will be described in detail with reference to FIGS. 3A-3B and 4A-4B later. The top surface 113′, e.g., the entire top surface, of the p-n junction diodes 113 may be within a range of about 20% to about 80% of a height, i.e., the perpendicular direction along the z-axis, of the cell contact hole 111. In other words, an arbitrary point of the top surface of the p-n junction diodes 113 may not be outside the range of about 20% and about 80% of the height of the cell contact hole 111, e.g., 0% of the height of the cell contact hole 111 may be on a top surface of the word line 102.

An ohmic layer 115 may be formed on the top surface of the p-n junction diodes 113 to reduce an ohmic contact resistance with the bottom electrode 119 to be formed thereon. The ohmic layer 115 may include a metal silicide, e.g., at least one of cobalt silicide, titanium silicide, nickel silicide, tantalum silicide, etc. For example, the ohmic layer 115 may be formed on the top surface of the p-n junction diodes 113 and may have a substantially almost uniform thickness. The ohmic layer 115 may be formed on the entire top surfaces of the p-n junction diodes 113.

At least a part of the cell contact hole 111 on the ohmic layer 115 may be filled with the bottom electrode 119. The bottom electrode 119 may electrically connect a storage device that is to be formed on a top portion of the bottom electrode 119 and the p-n junction diodes 113. The bottom electrode 119 may be formed of a carbon containing conductive material, e.g., graphite, carbon nanotube (CNT), and graphene, a nitrogen containing conductive material, e.g., titanium nitride (TiN), tantalum nitride (TaN), molybdenum nitride (MoN), tungsten nitride (WN), niobium nitride (NbN), titanium silicon nitride (TiSiN), tantalum aluminum nitride (TaAlN), titanium boron nitride (TiBN), zirconium silicon nitride (ZrSiN), tungsten silicon nitride (WSiN), tungsten boron nitride (WBN), zirconium aluminum nitride (ZrAlN), molybdenum silicon nitride (MoSiN), molybdenum aluminum nitride (MoAlN), tantalum silicon nitride (TaSiN), tantalum aluminum nitride (TaAlN), titanium oxynitride (TiON), titanium aluminum oxynitride (TiAlON), tungsten oxynitride (WON), tantalum oxynitride (TaON) or a combination of the listed items, a metal, e.g., titanium, tungsten, molybdenum, and tantalum, metal silicide such as titanium silicide, tantalum silicide, etc., or a combination of the listed items.

An insulation layer, e.g., a spacer-like insulation layer distinctive from the first interlayer insulation layer 107, is not formed between the bottom electrode 119 and the sidewall of the cell contact hole 111 in the cell contact hole 111. Thus, a bottom surface area of the bottom electrode 119 may be substantially the same as a top surface area of the ohmic layer 115. In addition, a bottom surface area of the ohmic layer 115 may be substantially the same as a top surface area of the p-n junction diodes 113. In other words, the entire sidewall of the bottom electrode 119 may directly contact the first interlayer insulation layer 107, i.e., the sidewall of the cell contact hole 111, so the contact surface area of the bottom electrode 119, the ohmic layer 115, and the p-n junction diodes 113 is maximized, thereby reducing contact resistance thereof.

A storage device 121 may be formed on top of the bottom electrode 119. The storage device 121 may include a capacitor, phase-change random access memory (PRAM), resistive random access memory (RRAM), ferroelectric random access memory (FRAM), and magnetic random access memory (MRAM). Although the storage device 121 is the PRAM in FIG. 2, the inventive concept is not limited thereto.

The PRAM may include a phase-change material layer, such as a chalcogenide compound. The phase-change material layer may include, for example, Ge—Sb—Te, As—Sb—Te, As—Ge—Sb—Te, Sn—Sb—Te, In—Sn—Sb—Te, Ag—In—Sb—Te, (Group 5 elements)-Sb—Te, (Group 6 elements)-Sb—Te, (Group 5 elements)-Sb—Se, (Group 6 elements)-Sb—Se, Ge—Sb—Te—Si, As—Sb—Te—Si, As—Ge—Sb—Te—Si, Sn—Sb—Te—Si, In—Sn—Sb—Te—Si, Ag—In—Sb—Te—Si, (Group 5 elements)-Sb—Te—Si, (Group 6 elements)-Sb—Te—Si, (Group 5 elements)-Sb—Se—Si, (Group 6 elements)-Sb—Se—Si, or a combination of the listed items.

The RRAM may include NiO, HfO₂, VO₂, TiO₂, Nb₂O₅, Al₂O₃, or a composite layer of the listed items.

The FRAM may include PZT (Pb(Zr, Ti)O₃), SBT (SrBi₂Ta₂O₃), BLT (Bi(La, Ti)O₃), PLZT (Pb(La, Zr)TiO₃), PNZT (Pb(Nb, Zr, Ti)O₃), BFO (BiFeO₃), BST (Ba(Sr, Ti)O₃), or a composite layer of the listed items.

The MRAM may include PtMn, NiMn, OsMn, IrMn, PtPdMn, PtCrMn, FeMn having a thickness of about 10 Å and about 100 Å, or a composite layer of the listed items as a ferromagnetic layer, Co, CoFe, NiFe having a thickness of about 5 Å and about 100 Å, or a composite layer of the listed items as the ferromagnetic layer, Co, CoFe, NiFe, having a thickness of about 5 Å and about 100 Å, or a composite layer of the listed items as a free layer, and AlO, MgO, or a composite layer of the listed items as a barrier layer.

Although the storage device 121 covers the entire top surface of the bottom electrode 119 in FIG. 2, the storage device 121 may cover a part of the top surface of the bottom electrode 119. Although the storage device 121 is located on the top portion of the cell contact hole 111 in FIG. 2, the storage device 121 may be confined in the cell contact hole 111.

A top electrode 123 and a bitline contact plug 127 may be disposed on top of the storage device 121.

The top electrode 123 may be formed of, e.g., at least one of aluminum (Al), copper (Cu), aluminum-copper (Al—Cu) alloy, aluminum-copper-silicon (Al—Cu—Si) alloy, tungsten silicide (WSi), titanium tungstenide (TiW), tantalum (Ta), molybdenum (Mo), tungsten (W), or a combination of the listed items. The top electrode 123 may be self-aligned with the storage device 121.

The bitline contact plug 127 may be formed of metal, e.g., at least one of titanium (Ti), tungsten (W), doped polysilicon, metal silicide, e.g., at least one of WSi, TiSi, CoSi, metal nitride such as TiN, TaN, WN, or a combination of the listed items.

The storage device 121, the top electrode 123, and the bitline contact plug 127 may be disposed for each cell contact hole 111. The storage device 121, the top electrode 123, and the bitline contact plug 127 may be electrically insulated from a neighboring storage device 121, top electrode 123, and bitline contact plug 127 by a second interlayer insulation layer 109.

The bit lines 131 may be disposed on a top portion of the bitline contact plug 127. The bit lines 131 may include, e.g., at least one of aluminum (Al), copper (Cu), aluminum-copper (Al—Cu) alloy, aluminum-copper-silicon (Al—Cu—Si) alloy, tungsten silicide (WSi), titanium tungsten compound (TiW), tantalum (Ta), molybdenum (Mo), tungsten (W), or a combination of the listed items.

FIGS. 3A and 3B are plan views of the cell contact hole 111 formed in the first interlayer insulation layer 107 on the word lines 102 according to an embodiment of the inventive concept. As described above, although the cell contact hole 111 may have a circular cross-section as shown in FIG. 1, the cell contact hole 111 may have an oval cross-section having major and minor axes as shown in FIG. 3A.

For example, referring to FIG. 3A, the cell contact hole 111 may have an oval shape in which a diameter in one direction is greater than a diameter in another direction perpendicular to the one direction. Although a diameter y1 in a y direction is greater than a diameter x1 in an x direction in FIG. 3A, the diameter x1 in the x direction may be greater than the diameter y1 in the y direction. Further, although the major axis and the minor axis are in the y direction and the x direction, respectively, in FIG. 3A, the major axis and the minor axis of the oval cross-section of the cell contact hole 111 may have arbitrary perpendicular two directions. Further, an aspect ratio of the oval cross-section may be defined as a ratio of the major axis length and the minor axis length, e.g., from about 1.2 to about 3.

In another example, referring to FIG. 3B, the cell contact hole 111 may have a rectangular cross-section having different lengths of two adjacent sides. Although a length y2 in the y direction is greater than a length x2 in the x direction in FIG. 3B, the length x2 in the x direction may be greater than the length y2 in the y direction. Further, although the two adjacent sides are along the y direction and the x direction, respectively, in FIG. 3B, the two adjacent sides of the rectangular cross-section of the cell contact hole 111 may have arbitrary perpendicular two directions. An aspect ratio of the rectangular cross-section may be defined as a ratio of a length of a relatively long side of the two adjacent sides with respect to a length of a relatively short side thereof, e.g., from about 1.2 to about 3.

FIGS. 4A and 4B are perspective views of the cell contact hole 111, the p-n junction diode 113 formed in the cell contact hole 111, and the ohmic layer 115, according to an embodiment of the inventive concept.

Referring to FIG. 4A, the cell contact hole 111 may have an oval cross-section having the major and minor axes as shown in FIG. 3A. The cell contact hole 111 may extend in the z direction. In this regard, the z direction may be defined as a direction perpendicular to the x direction and the y direction. As described above, a cross-sectional area of the cell contact hole 111 in a horizontal direction, i.e. a cross-section of the cell contact hole 111 cut in parallel to an xy plane, may or may not vary according to a location of the cell contact hole 111 in the z direction.

Although the n type semiconductor layer 113n is disposed under the p type semiconductor layer 113p in FIG. 4A, the n type semiconductor layer 113n may be alternatively disposed above the p type semiconductor layer 113p.

An interface between the p-n junction diode 113 and the ohmic layer 115 disposed on the top portion of the p-n junction diode 113 may form an angle θ1 with respect to the z axis as illustrated in FIG. 4A. An angle formed between an arbitrary plane and the z axis is defined as an angle formed between the z axis and a line segment obtained by perpendicularly projecting the z axis onto the arbitrary plane.

The angle θ1 may be an acute angle rather than a right angle, for example, from about 30 degrees to about 80 degrees. An interface between the top surface of the ohmic layer 115 and the bottom electrode located thereon may form an angle θ2 with the z axis. For example, when the ohmic layer 115 is formed by a self-aligned silicidation (salicide) process, the ohmic layer 115 may have a substantially uniform thickness and the angle θ2 may be substantially the same as the angle θ1. Thus, the angle θ2 may be, for example, from about 30 degrees to about 80 degrees. It is noted, however, that ohmic layer 115 may be formed by other methods.

An interface between the p type semiconductor layer 113p and the n type semiconductor layer 113n may form an angle θ3 with the z axis. The angle θ3 may have various angles according to the angle θ1 and a method of forming the p type semiconductor layer 113p or the n type semiconductor layer 113n that is located at a top portion of the p-n junction diode 113. For example, when the p type semiconductor layer 113p or the n type semiconductor layer 113n that is located at the top portion of the p-n junction diode 113 is formed by injecting ions, the angle θ3 may be substantially the same as or relatively similar to the angle θ1. The angle θ3 may be, for example, from about 30 degrees to about 80 degrees.

Referring to FIG. 4B, the cell contact hole 111 may have a rectangular cross-section having different lengths of two adjacent sides as shown in FIG. 3B. The redundant descriptions between FIGS. 4A and 4B will be omitted below.

The interface between the p-n junction diode 113 and the ohmic layer 115 disposed on top of the p-n junction diode 113 may form the angle θ1 with respect to the z axis. The angle θ1 may be an acute angle rather than a right angle, for example, from about 30 degrees to about 80 degrees. The interface between the top surface of the ohmic layer 115 and the bottom electrode located thereon may form the angle θ2 with the z axis. When the ohmic layer 115 is formed by a salicide process, the angle θ2 may be substantially the same as the angle θ1, and may be, for example, from about 30 degrees to about 80 degrees.

The interface between the p type semiconductor layer 113p and the n type semiconductor layer 113n may form the angle θ3 with the z axis. The angle θ3 may have various angles according to the angle θ1 and a method of forming the p type semiconductor layer 113p or the n type semiconductor layer 113n that is located at a top portion of the p-n junction diode 113. If the p type semiconductor layer 113p or the n type semiconductor layer 113n that is located at the top portion of the p-n junction diode 113 is formed by injecting ions, the angle θ3 may be substantially the same as or relatively similar to the angle θ1. The angle θ3 may be, for example, from about 30 degrees to about 80 degrees.

As described above, the top surface of the p-n junction diode 113 may be inclined, e.g., slanted, with respect to the semiconductor substrate. As such, a surface area of the top surface 113′ of the p-n junction diode 113 may be larger that a bottom surface 113″ thereof. Accordingly, the storage device formed on and in parallel to the top surface of the p-n junction diode 113 may have an increased surface area of a bottom thereof, e.g., as compared to a conventional storage device. Therefore, the storage device and the p-n junction diode 113 may have an increased contact surface area, thereby reducing resistance due to an ohmic contact. As a result, device reliability may be further enhanced.

In contrast, a conventional switching device may have top and bottom surface parallel to each other, so a relatively small area of the switching device may contact a bottom electrode of a storage device. The conventional switching device may further include a spacer on sidewalls of a cell contact hole, which may further reduce the contact area between the switching device and the bottom electrode of the storage device. As a result, contact resistance increases, which in turn, increases power consumption and causes unstable operating characteristics.

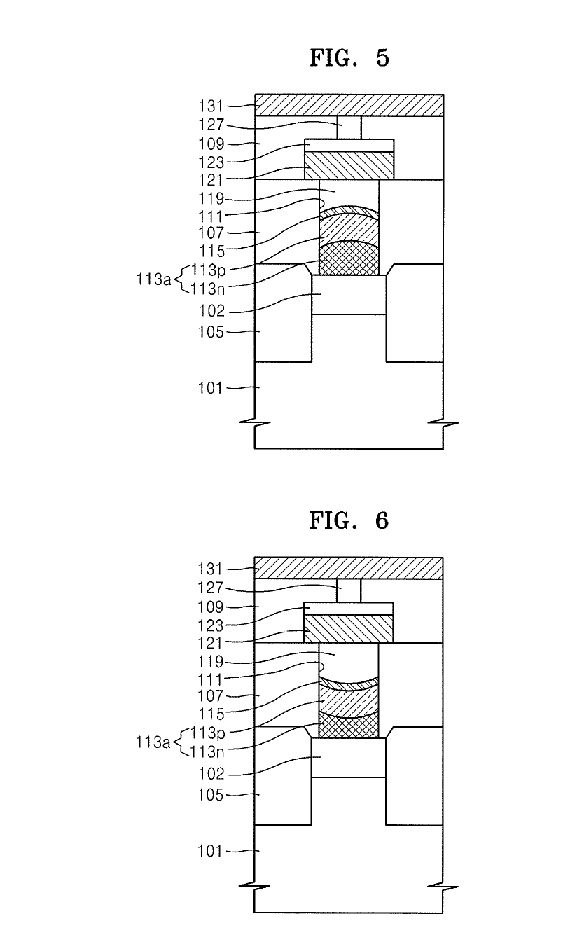

FIGS. 5 through 10 are cross-sectional views of a semiconductor device, according to embodiments of the inventive concept.

Referring to FIGS. 5 and 6, a semiconductor device may be substantially the same as that described previously with reference to FIGS. 1-2, with the exception of an upper surface of a p-n junction diode 113a having a concave or convex form with respect to an upper direction. It is possible to adjust a shape of a top surface of the p-n junction diode 113a according to SEG conditions. Although the top surface of the p-n junction diode 113a forms a part of a sphere in FIGS. 5 and 6, the top surface of the p-n junction diode 113a may form a circular cone according to SEG conditions.

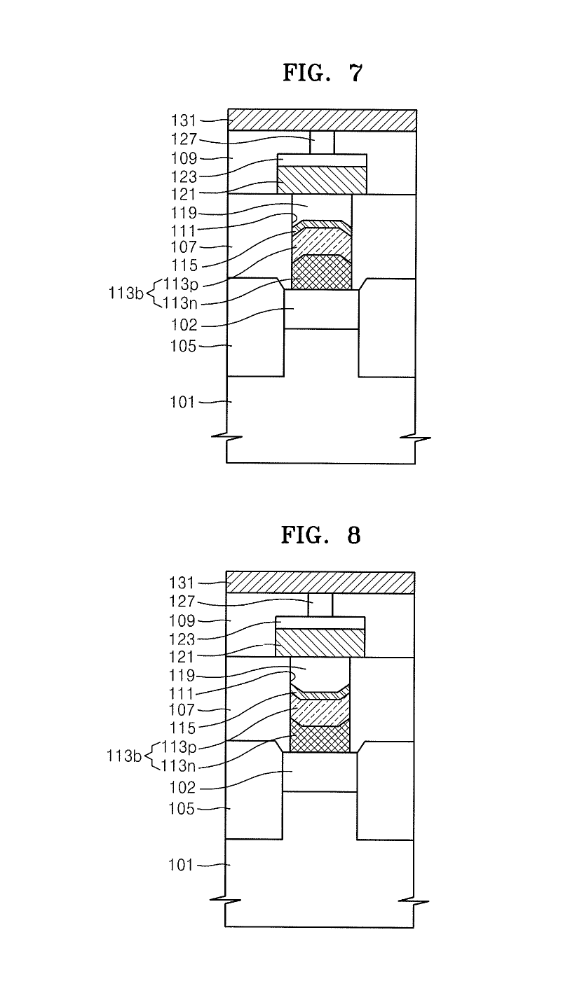

Referring to FIGS. 7 and 8, a semiconductor device may be substantially the same as that described previously with reference to FIGS. 1-2, with the exception of a center portion of a top surface of a p-n junction diode 113b having a plane substantially in parallel to the semiconductor substrate 101, and a circumferential portion thereof may be inclined with respect to the center portion. In other words, the upper surface of the p-n junction diode 113b may have a first portion that is substantially parallel to the semiconductor substrate 101 and two second portion at opposite ends of the first portion and inclined, e.g., angled or curved, with respect to the first portion flat portion. The center portion of the top surface may protrude upward compared to the circumferential portion (FIG. 7) or may recede downward (FIG. 8).

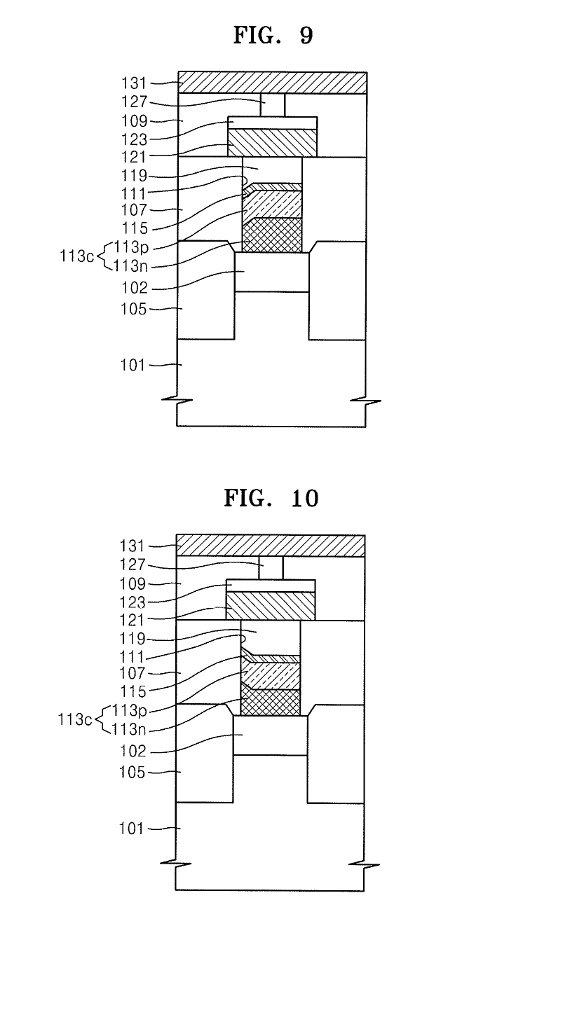

Referring to FIGS. 9 and 10, a semiconductor device may be substantially the same as that described previously with reference to FIGS. 1-2, with the exception of a top surface of the p-n junction diode 113c being divided into only two regions. That is, the top surface may be divided into a first region substantially in parallel to the semiconductor substrate 101 and a second region inclined with the first region at a predetermined angle. The first region may be continuous within a predetermined region of the cell contact hole 111. The second region may be continuously adjacent to the first region.

Although a shape of an interface of the p-n junction in FIGS. 5 through 10 is the same as or similar to a shape of the top surface of the p-n junction diode 113, the shapes may be different from each other according to a manufacturing method. If an impurity region located at a top portion (the p-type semiconductor layer 113p of FIGS. 5 through 10) is not formed by injecting ions but by a heterogeneous epitaxial growth, interfaces of the p-n junction diode 113 may have different shapes.

Although a shape of a top surface of the ohmic layer 115 in FIGS. 5 through 10 may be the same as or similar to the shape of the top surface of the p-n junction diode 113, the shapes may be different from each other according to a manufacturing method. For example, if the ohmic layer 115 is formed by using a salicide method, the shape of a top surface of the ohmic layer 115 in FIGS. 5 through 10 may be the same as or similar to the shape of a corresponding the top surface of the p-n junction diode. However, the ohmic layer 115 may be formed into a different shape by using different methods.

The top surfaces of the p-n junction diodes in FIGS. 5 through 10 may be formed to have an increased contact surface between the top surface of the p-n junction diode 113 and the ohmic layer 115, and an increased contact surface between the ohmic layer 115 and the bottom electrode 119. As such, resistance may be lowered to enhance device performance, e.g., at low power.

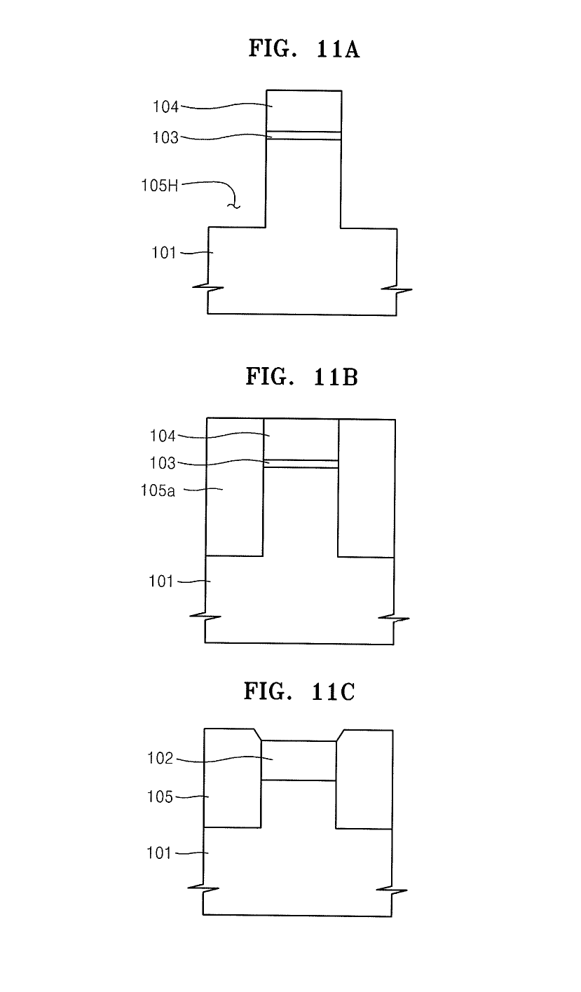

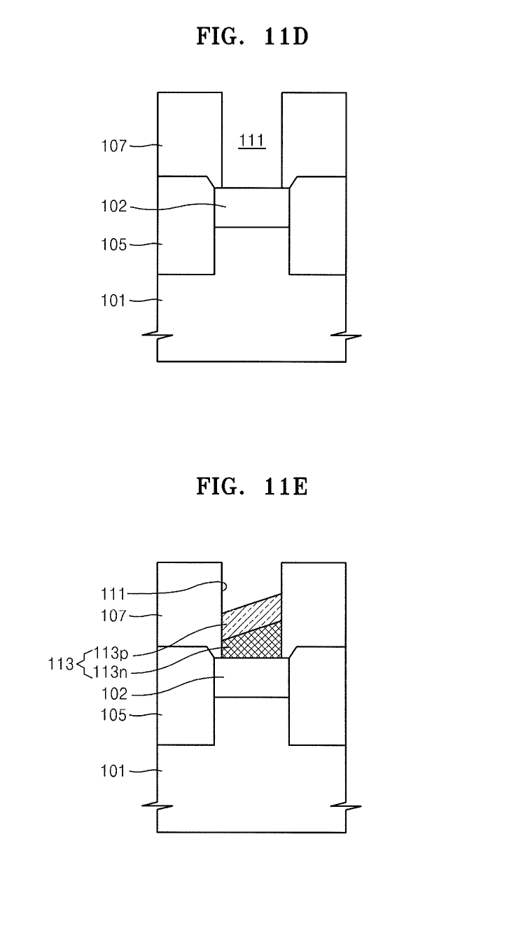

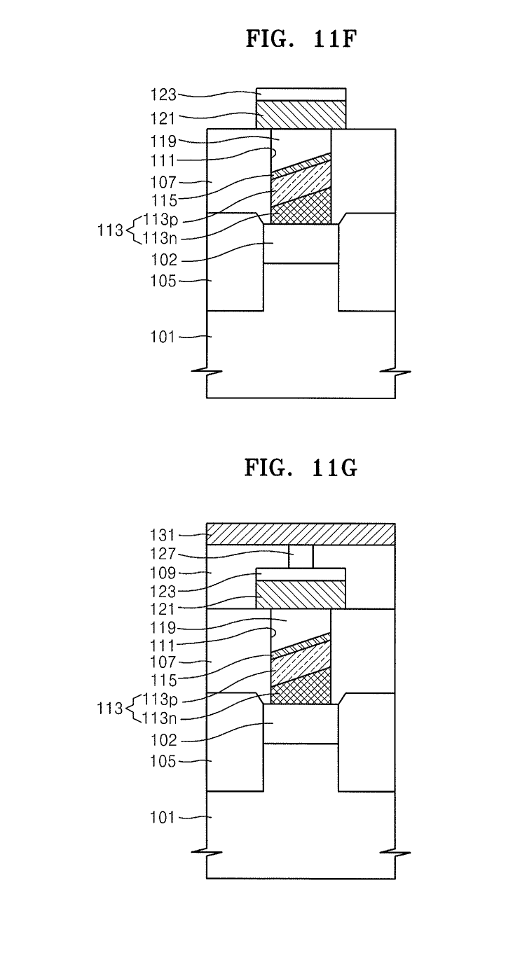

FIGS. 11A through 11G are cross-sectional views of stages in a method of manufacturing a semiconductor device, according to an embodiment of the inventive concept. In particular, FIGS. 11A through 11G show a portion Y-Y′ of FIG. 2.

Referring to FIG. 11A, a pad oxide layer 103 and a mask layer 104 may be sequentially formed on the semiconductor substrate 101. The semiconductor substrate 101 was described in detail above, and thus further description thereof will be omitted.

The pad oxide layer 103 may be formed by using a thermal oxidation process, and, for example, may have a thickness of about 100 Å to about 150 Å. The pad oxide layer 103 prevents the semiconductor substrate 101 from being contaminated and relieves a stress due to formation of the mask layer 104.

Then, the mask layer 104 may be patterned in such a way that a portion where a device isolation layer is to be formed is exposed. A trench 105H corresponding to the device isolation layer may be formed by etching the pad oxide layer 103 and the semiconductor substrate 101 by using the mask layer 104 as an etching mask. A sidewall of the trench 105H may have an inclination angle.

Referring to FIG. 11B, the trench 105H may be buried by a device isolation layer 105a. The device isolation layer 105a may be formed of BPSG (boro-phospho-silicate glass), TOSZ (tonen silazene), USG (undoped silicate glass), SOG (spin-on glass), FOX (flowable oxide), TEOS (tetraethylortho silicate) or HDP CVD (high density plasma chemical vapor deposition) oxide. For example, the trench 105H may be formed of middle temperature oxide. The device isolation layer 105a may be formed by forming a material layer, e.g., an insulation material or a dielectric material as described above, and planarizing the material layer by using the mask layer 104 as a planarization stop layer.

The material layer may be formed by performing chemical vapor deposition (CVD), physical vapor deposition (PVD) such as sputtering, or atomic layer deposition (ALD). The material layer may be planarized by performing a chemical mechanical polishing (CMP) process or an etch-back process. However, the inventive concept is not limited thereto.

Alternatively, a thermal oxide layer (not shown) for fixing damage due to etching of the semiconductor substrate 101 may be formed on a sidewall and bottom of the trench 105H before the device isolation layer 105a is formed. A nitride layer (not shown) for reducing a leakage current may be further formed on the thermal oxide layer.

Referring to FIG. 11C, the mask layer 104 may be removed by using a wet-etching method. Then, the device isolation layer 105 may be formed by planarizing the device isolation layer 105a using the pad oxide layer 103 as a planarization stop layer. The planarization may be performed, for example, by chemical mechanical polishing. Next, the pad oxide layer 103 may be removed. Then, the word lines 102 may be formed on the active regions. The word lines 102 may be formed by doping impurities on the active regions. The impurities may include n type impurities such as arsenic (As), phosphorus (P), antimony (Sb), bismuth (Bi), or p type impurities such as boron (B), indium (In), gallium (Ga). Optionally, an annealing process may be further performed after injecting the impurities.

Referring to FIG. 11D, the first interlayer insulation layer 107 may be formed on the device isolation layer 105 and the word lines 102. Then, the cell contact hole 111 may be formed. The first interlayer insulation layer 107 may be formed by using CVD, PVD such as sputtering, ALD, etc. The cell contact hole 111 may be formed by forming a photoresist pattern (not shown) and etching an exposed portion of the first interlayer insulation layer 107 by using the photoresist pattern as a mask.

A horizontal cross-section of the cell contact hole 111 may be, e.g., circular (as shown in FIG. 1), oval (as shown in FIG. 3A), or rectangular (as shown in FIG. 3B). If the cell contact hole 111 has an oval or rectangular cross-section as described above, an aspect ratio of the cell contact hole 111 may be about 1.2 to about 3.

Referring to FIG. 11E, the p-n junction diode 113 is formed in the cell contact hole 111. A diode material layer (not shown) may be grown in the cell contact hole 111 from the word lines 102 to form the p-n junction diode 113. In this regard, the diode material layer may be formed by using a SEG. In particular, heterogeneous expitaxial growth may be performed to form the diode material layer to have the same conductive type as the word lines 102.

When the diode material layer grows by using the SEG, if the cross-sectional shape of the cell contact hole 111 has an aspect ratio of about 1.2 to about 3, a top surface of the diode material layer may have a predetermined inclination. That is, when the aspect ratio is about 1.2 to about 3, the angle θ1, i.e., the angle between the top surface of the diode material layer and an axial direction of the cell contact hole 111, may be about 30 degrees to about 80 degrees. A pressure of a SEG process may be, for example, about 20 Torr to about 200 Torr. It is noted that the axial direction of the contact hole 111 refers to a longitudinal direction of the contact hole, e.g., along the z direction.

In this regard, if HCl is injected for cleaning, a volumetric flow rate of HCl may be about 150 sccm to about 350 sccm, and may be appropriately adjusted according to a used Si source material. More specifically, a ratio of the number of Si atoms of the Si source to the number of HCl molecules may be about 1:9 to about 1:20.

The SEG process conditions described above are used to make the angle θ1 about 30 degrees to about 80 degrees.

Thereafter, impurities having an opposite conductive type to the word lines 102 are injected into a top portion of the diode material layer to a predetermined depth. Injection energy and density of the impurities may be appropriately adjusted according to a dimension of the diode material layer and an impurity density of the diode material layer. Such injection of ions may result in the formation of the p-n junction diode 113 including the p-type semiconductor layer 113p above the n-type semiconductor layer 113n.

Although the p-type semiconductor layer 113p is located above the n-type semiconductor layer 113n in FIG. 11E, the n-type semiconductor layer 113n may be located above the p-type semiconductor layer 113p. In this regard, the word lines 102 may have p-type conductivity.

Referring to FIG. 11F, the ohmic layer 115 may be formed on top of the p-type semiconductor layer 113p. The ohmic layer 115 may be formed by using a salicide process as described above. For example, a metal layer formed of metal, e.g., cobalt, titanium, tantalum, nickel, or tungsten, may be conformally formed on top of the p-type semiconductor layer 113p, followed by performing thermal treatment on the metal. Silicide of each of the metal may be formed as the ohmic layer 15 through the thermal treatment. A remaining portion of the metal layer may be removed by using a wet-etching method after forming the ohmic layer 115.

Thereafter, the bottom electrode 119 is formed on the top portion of the ohmic layer 115. The bottom electrode 119 may be formed by using, for example, CVD, PVD, spin coating, or ALD, according to a type of the material. However, the inventive concept is not limited thereto. It is noted that while a bottom of the bottom electrode 119, i.e. a surface contacting the ohmic layer 115, may be inclined with respect to the semiconductor substrate 110, a top surface of the bottom electrode 119 may be substantially parallel with the semiconductor substrate 110 and substantially level with a top surface of the first interlayer insulation layer 107.

As a result, an entire top surface of the ohmic layer 115 may contact an entire bottom surface of the bottom electrode 119. In addition, an entire bottom surface of the ohmic layer 115 may contact an entire top surface of the p-n junction diode 113.

Then, the storage device 121 and the top electrode 123 are sequentially formed on the top portion of the bottom electrode 119. Although the storage device 121 may be formed in the cell contact hole 111 as occasions demand, the storage device 121 may be formed outside the cell contact hole 111. The storage device 121 and the top electrode 123 may be formed by sequentially forming a storage device material layer (not shown) and a top electrode material layer (not shown) and patterning the storage device material layer and the top electrode material layer. Although the storage device material layer and the top electrode material layer may be formed by using CVD, PVD, or ALD, the inventive concept is not limited thereto. The storage device material layer and the top electrode material layer may be patterned by using a photolithography method.

Referring to FIG. 11G, the second interlayer insulation layer 109 that covers the storage device 121 and the top electrode 123 is formed, a contact hole for forming the bitline contact plug 127 is formed, and the bitline contact plug 127 is formed. The second interlayer insulation layer 109 may be formed as the first interlayer insulation layer 107 is formed, and its detailed description is omitted. The contact hole may be formed by using a photolithography method. The bitline contact plug 127 may be formed in the contact hole by using CVD, PVC, or ALD. Then, a CMP or etch-back process may be used to planarize the second interlayer insulation layer 109 for a separation of nodes. Subsequently, the bit lines 131 may be formed on top of the bitline contact plugs 127.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A semiconductor device, comprising:
an insulation layer including a cell contact hole; and
a switching device in the cell contact hole, at least a part of a top surface of the switching device being inclined with respect to an axial direction of the cell contact hole.

2. The semiconductor device as claimed in claim 1, further comprising:
a storage device electrically connected to the switching device; and
a plurality of bitlines electrically connected to the storage device.

3. The semiconductor device as claimed in claim 2, further comprising:
a bottom electrode formed at a bottom portion of the storage device; and
a top electrode formed at a top portion of the storage device.

4. The semiconductor device as claimed in claim 3, wherein the bottom electrode is in the cell contact hole, an entire sidewall of the bottom electrode directly contacting a sidewall of the cell contact hole.

5. The semiconductor device as claimed in claim 2, wherein the storage device is at least one of a capacitor, a phase-change random access memory (PRAM), a resistive random access memory (RRAM), a ferroelectric random access memory (FRAM), and a magnetic random access memory (MRAM).

6. The semiconductor device as claimed in claim 2, further comprising a metal silicide layer inside the cell contact hole and on a top surface of the switching device.

7. The semiconductor device as claimed in claim 6, wherein an entire top surface of the metal silicide layer contacts a bottom surface of a bottom electrode of the storage device, and an entire bottom surface of the metal silicide layer contacts the top surface of the switching device.

8. The semiconductor device as claimed in claim 1, wherein the switching device is a diode.

9. The semiconductor device as claimed in claim 8, wherein an angle between the top surface of the diode and the axial direction of the cell contact hole is about 30 degrees to about 80 degrees.

10. The semiconductor device as claimed in claim 1, wherein a cross-section of the cell contact hole is oval or rectangular.

11. The semiconductor device as claimed in claim 10, wherein an aspect ratio of the cross-section of the cell contact hole is about 1.2 to about 3.

12. The semiconductor device as claimed in claim 1, wherein the top surface of the switching device is located between about 20% and about 80% of a height of the cell contact hole.

13. The semiconductor device as claimed in claim 1, wherein a storage device overlaps an entire top surface of the switching device, a surface area of the top surface of the switching device being larger than a surface of area of a bottom of the cell contact hole.

14. The semiconductor device as claimed in claim 1, wherein at least a portion of the top surface of the switching device and a bottom surface of the switching device are not parallel, the bottom surface of the switching device being substantially perpendicular to the axial direction of the cell contact hole, and a bottom surface of a storage device being on and parallel to the top surface of the switching device.

15. The semiconductor device as claimed in claim 14, wherein a surface area of the top surface of the switching device is larger than a surface area of the bottom surface of the switching device.

16. The semiconductor device as claimed in claim 1, wherein a bottom of a storage device is on and parallel to the top surface of the switching device, a surface area of the top surface of the switching device being larger than a surface area of a bottom of the cell contact hole.

17. A semiconductor device, comprising:
a substrate; and
a switching device with a p-n junction on the substrate, the substrate being a seed crystal for the switching device, and at least a part of a top surface of the switching device being inclined with respect to a surface of the substrate.

18. The semiconductor device as claimed in claim 17, wherein an interface of the p-n junction is non parallel to the surface of the substrate.

19. The semiconductor device as claimed in claim 17, wherein the switching device is epitaxially grown from the substrate, the p-n junction being within a portion of an the epitaxially grown switching device.

20. (canceled)
